(19) United States
(12) Patent Application Publication
(10) Pub. No.: US 2025/0022824 A1
(43) Pub. Date: Jan. 16, 2025

(54) SEMICONDUCTOR PACKAGE AND METHOD FOR FABRICATING THE SAME

(71) Applicant: SAMSUNG ELECTRONICS CO., LTD., Suwon-si (KR)

(72) Inventor: YOUNGBAE KIM, Suwon-si (KR)

(73) Assignee: SAMSUNG ELECTRONICS CO., LTD., Suwon-si (KR)

(21) Appl. No.: 18/416,608

(22) Filed: Jan. 18, 2024

(30) Foreign Application Priority Data
Jul. 12, 2023 (KR) 10-2023-0090480

(51) Int. Cl. H01L 23/00; H01L 23/31; H01L 23/48; H01L 25/065

(52) U.S. Cl. CPC H01L 24/06; H01L 23/3128; H01L 23/481; H01L 24/08; H01L 25/0652; H01L 2224/0603; H01L 2224/08145; H01L 2224/08225; H01L 2924/1431; H01L 2924/1434; H01L 2924/181

(57) ABSTRACT

A semiconductor package includes a first semiconductor chip including a first semiconductor layer including a surface which extends in a first direction; and a first connection pad provided on the surface of the first semiconductor; and a second semiconductor chip including a second semiconductor layer; and a second connection pad provided on a surface of the second semiconductor layer. The first connection pad is directly connected to the second connection pad and a ratio of a width of the second connection pad in the first direction to a width of the first connection pad in the first direction is less than or equal to 1.1 and greater than or equal to 0.5.

### CROSS-REFERENCE TO RELATED APPLICATION

This application claims priority to Korean Patent Application No. 10-2023-0090480 filed on Jul. 12, 2023, in the Korean Intellectual Property Office, the disclosure of which is incorporated by reference herein in its entirety.

### BACKGROUND

### 1. Field

Embodiments of the present disclosure relates to a semiconductor package and a manufacturing method thereof.

### 2. Description of Related Art

In a semiconductor packaging process, when a plurality of semiconductor chips are bonded or semiconductor chips and a substrate are bonded, as a pitch between bonding pads narrows, a process of directly bonding pads without solder balls or solder bumps is being developed.

Hybrid bonding is the bonding of a plurality of semiconductor chips or semiconductor chip and a substrate by using bonding properties between the same materials. According to such hybrid bonding, an input/output (I/O) having a fine pitch may be formed.

In the hybrid bonding process, as bonding pads are exposed to high temperatures and thermally expand, the pads may be delaminated or cracks may occur at the interface.

### SUMMARY

Example embodiments provide a semiconductor package including a structure in which reliability of a junction can be improved.

According to an aspect of an example embodiment, a semiconductor package includes: a first semiconductor chip including: a first semiconductor layer including a surface which extends in a first direction; and a first connection pad provided on the surface of the first semiconductor layer; and a second semiconductor chip including: a second semiconductor layer; and a second connection pad provided on a surface of the second semiconductor layer, wherein the first connection pad is directly connected to the second connection pad, wherein the first connection pad is provided on the second connection pad in a second direction perpendicular to the first direction, and wherein a ratio of a width of the second connection pad in the first direction to a width of the first connection pad in the first direction is less than or equal to 1.1 and greater than or equal to 0.5.

According to an aspect of an example embodiment, a semiconductor package includes: a first semiconductor chip including: a first semiconductor layer including a surface which extends in a first direction; and a first connection pad provided on the surface of the first semiconductor layer; and a second semiconductor chip including: a second semiconductor layer; and a second connection pad provided on a surface of the second semiconductor layer, wherein the first connection pad is directly connected to the second connection pad, wherein the first connection pad is provided on the second connection pad in a second direction perpendicular to the first direction, and wherein a ratio of a thickness of the first connection pad in the second direction to a thickness of the second connection pad in the second direction is greater than or equal to 1.6 and less than or equal to 2.1.

According to an aspect of an example embodiment, a semiconductor package includes: an interposer; a logic die provided on the interposer; and a high bandwidth memory provided on the interposer, wherein the high bandwidth memory includes: a buffer die; a first semiconductor chip provided on the buffer die and including: a first semiconductor layer including a surface which extends in a first direction; and a first connection pad provided on the surface of the first semiconductor layer; and a second semiconductor chip including: a second semiconductor layer; and a second connection pad provided on a surface of the second semiconductor layer, wherein the first connection pad is directly connected to the second connection pad, wherein the first connection pad is provided on the second connection pad in a second direction perpendicular to the first direction, wherein a ratio of a width of the second connection pad in the first direction to a width of the first connection pad in the first direction is less than or equal to 1.1 and greater than or equal to 0.5, and wherein the semiconductor package further includes a molding material provided on the buffer die and molding the first semiconductor chip and the second semiconductor chip.

### BRIEF DESCRIPTION OF THE DRAWINGS

The above and other aspects and features will be more apparent from the following description of one or more example embodiments taken in conjunction with the accompanying drawings, in which:

FIG. 1 is a diagram illustrating a semiconductor package according to one or more example embodiments.

FIG. 2A is an enlarged cross-sectional view of a junction of a semiconductor package according to one or more example embodiments.

FIG. 2B is an enlarged cross-sectional view of region ‘B’ of FIG. 2A, according to one or more example embodiments.

FIG. 3 is a diagram illustrating the size of stress on connection pads according to a width ratio, according to one or more example embodiments.

FIG. 4A is an enlarged cross-sectional view of a junction of a semiconductor package according to one or more example embodiments.

FIG. 4B is an enlarged cross-sectional view of region ‘C’ of FIG. 4A, according to one or more example embodiments.

FIG. 5 is a diagram showing the size of stress applied to an upper pad and a lower pad according to a thickness ratio of the upper pad and the lower pad, according to one or more example embodiments.

FIG. 6 is a diagram illustrating a semiconductor package according to one or more example embodiments.

FIG. 7 is a cross-sectional view illustrating a 2.5D semiconductor package including a junction structure according to one or more example embodiments.

FIG. 8 is a cross-sectional view illustrating a 3D semiconductor package including a junction structure according to one or more example embodiments.

### DETAILED DESCRIPTION

Hereinafter, one or more example embodiments will be described in detail with reference to the accompanying drawings. It will be apparent to those skilled in the art that the described one or more example embodiments may be modified in various different ways, without departing from the spirit or scope of the following claims.

The drawings and description of one or more example embodiments are to be regarded as illustrative in nature and not restrictive. Like reference numerals designate like elements throughout the following description.

Size and thickness of each constituent element in the drawings are illustrated according to one or more example embodiments for better understanding and ease of description, however, one or more example embodiments are not limited thereto. In the drawings, the thickness of layers, films, panels, regions, etc., may be exaggerated for clarity. In the drawings, the thickness of some layers and regions may be exaggerated for ease of description.

In addition, it will be understood that when an element such as a layer, film, region, or substrate is referred to as being “above” or “on” another element, it may be directly on the other element or intervening elements may also be present. In contrast, when an element is referred to as being “directly on” another element, there are no intervening elements present. Further, when an element is referred to as being “above” or “on” a reference element, it may be provided above or below the reference element, and it is not necessarily referred to as being provided “above” or “on” in a direction opposite to gravity.

Further, in addition, unless explicitly described to the contrary, the word “comprise”, and variations such as “comprises” or “comprising”, may be understood to imply the inclusion of stated elements but not the exclusion of any other elements.

Further, throughout the description of one or more example embodiments, the phrase “in a plan view” or “on a plane” may mean viewing a target portion from the top, and the phrase “in a cross-sectional view” or “on a cross-section” may mean viewing a cross-section formed by vertically cutting a target portion from the side.

Technical solutions obtainable from one or more example embodiments are non-limited the above-mentioned technical solutions. And, other unmentioned technical solutions will be apparent from the following description by those having ordinary skill in the technical field to which one or more example embodiments pertain.

Hereinafter, semiconductor package according to one or more example embodiments will be described with reference to drawings.

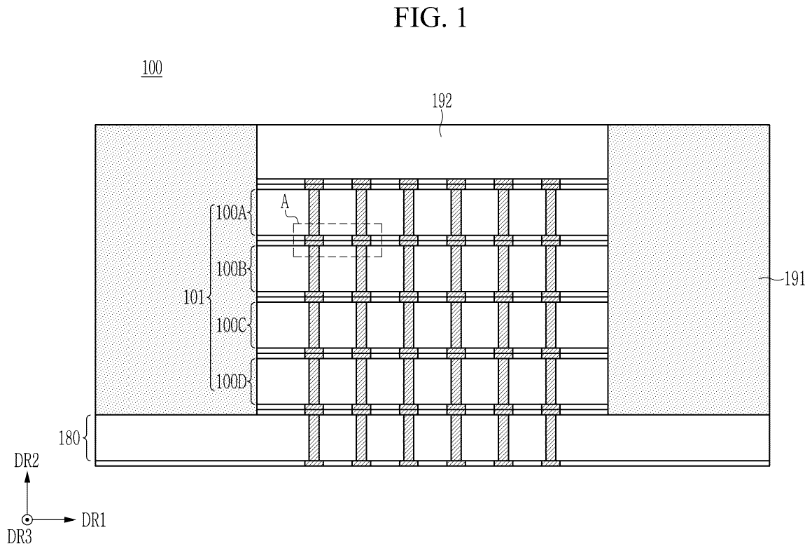

FIG. 1 is a diagram illustrating a semiconductor package according to one or more example embodiments.

Referring to FIG. 1, a semiconductor package 100 may include a semiconductor chip stacking structure 101, a lower die 180, a molding material 191, and a dummy silicon layer 192.

The semiconductor chip stacking structure 101 may have a structure in which a plurality of semiconductor chips 100A, 100B, 100C and 100D are stacked in one direction (e.g., in a second direction DR2). The semiconductor chip stacking structure 101 may be disposed on the lower die 180. In one or more example embodiments, the lower die 180 may have a larger width in a first direction DR1 compared to the semiconductor chip stacking structure 101.

In one or more example embodiments, the semiconductor package 100 may include high bandwidth memory (HBM). Each of the plurality of semiconductor chips 100A, 100B, 1000 and 100D stacked on the semiconductor chip stacking structure 101 may be a memory chip (e.g., DRAM), and the lower die 180 may be a buffer die. In the following one or more example embodiments, the semiconductor package 100 will be described as including a high bandwidth memory as an example, but one or more example embodiments are not limited to the high bandwidth memory.

The semiconductor chip stacking structure 101 and the lower die 180 may be bonded by hybrid bonding. Each of the semiconductor chips 100A, 100B, 1000 and 100D included in the semiconductor chip stacking structure 101 may be bonded to each other through hybrid bonding. Hybrid bonding may be performed by a junction included in each of the semiconductor chips 100A, 100B, 1000 and 100D or the lower die 180. The junction may be a portion where the semiconductor chips contact each other when the plurality of semiconductor chips 100A, 100B, 1000 and 100D are stacked and connected to each other. Alternatively, the junction may be a portion where one of the semiconductor chips 100A, 100B, 1000 and 100D and the lower die 180 contact each other when any one of the plurality of semiconductor chips 100A, 100B, 1000 and 100D and the lower die 180 are connected to each other.

Hybrid bonding comprises bonding two devices by fusing the same materials of the two devices using bonding properties of the same material. For example, in a junction, metal-to-metal bonding and non-metal-to-non-metal bonding may mean that two devices are bonded to each other. According to hybrid bonding, it may be possible to form input/output (I/O)s with a fine pitch.

Specifically, when two semiconductor chips are bonded to each other, junctions of each semiconductor chip may include one or more metal pads and an insulating layer adjacent to the metal pads. In this case, in the junction, the metal pads may be bonded to each other, and the insulating layers may be bonded to each other.

In one or more example embodiments, the width of the metal pad of the upper semiconductor chip and the width of the lower semiconductor chip may be predetermined so that the width of the metal pad of the upper semiconductor chip relative to the width of the metal pad of the lower semiconductor chip has a predetermined ratio.

In one or more example embodiments, the thickness of the metal pad of the upper semiconductor chip and the thickness of the lower semiconductor chip may be predetermined so that the thickness of the metal pad of the upper semiconductor chip relative to the thickness of the metal pad of the lower semiconductor chip has a predetermined ratio.

The molding material 191 may be disposed on the lower die 180 and may mold the semiconductor chip stacking structure 101. The molding material 191 may serve to protect and insulate the semiconductor chip stacking structure 101. In one or more example embodiments, the molding material 191 may comprise a thermosetting resin such as epoxy resin. In one or more example embodiments, the molding material 191 may be an epoxy molding compound (EMC). In one or more example embodiments, the process of molding with the molding material 191 may include a compression molding or transfer molding process.

The dummy silicon layer 192 may be configured to dissipate heat generated in the high bandwidth memory to the outside. The dummy silicon layer 192 may include crystalline silicon. The thermal conductivity of silicon may have a greater value than the thermal conductivity of the molding material 191. Heat generated in the high bandwidth memory can be effectively dissipated by the dummy silicon layer 192 including silicon.

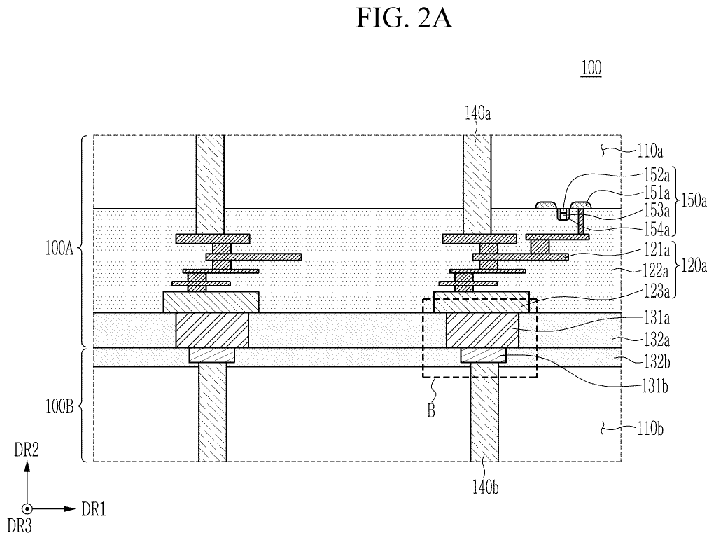

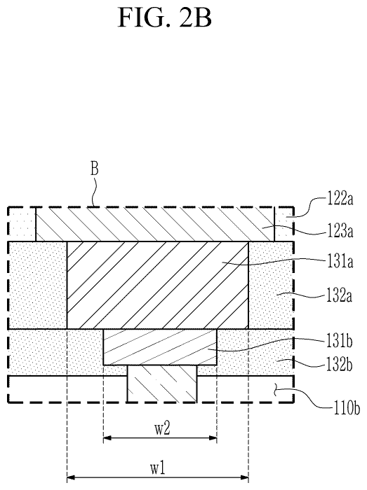

FIGS. 2A and 2B are diagrams for describing in detail a configuration of a junction of a semiconductor package according to one or more example embodiments.

Specifically, FIG. 2A is an enlarged cross-sectional view of a junction of a semiconductor package according to one or more example embodiments, and FIG. 2B is an enlarged cross-sectional view of a region ‘B’ of FIG. 2A, according to one or more example embodiments.

For example, FIG. 2A may show a junction where the first semiconductor chip 100A and the second semiconductor chip 100B contact each other in the semiconductor package of FIG. 1. For example, FIG. 2A may be an enlarged view of portion ‘A’ in the semiconductor package 100 of FIG. 1.

The first semiconductor chip 100A may be connected to the second semiconductor chip 100B in a flip chip method. For example, in FIG. 2A, the junction may be where a surface of the first semiconductor chip 100A and a surface of the second semiconductor chip 100B are bonded together.

Referring to FIG. 2A, the junction of the first semiconductor chip 100A may include a first semiconductor layer 110a, a wiring structure 120a, a first connection pad 131a, a first insulating layer 132a, a first through electrode 140a and a semiconductor element 150a.

The first semiconductor layer 110a may include, for example, a semiconductor element such as silicon (Si) or germanium (Ge), or silicon carbide (SiC), gallium arsenide (GaAs), indium arsenide (InAs), or a compound semiconductor such as indium phosphide (InP).

The semiconductor element 150a may be provided between the first semiconductor layer 110a and the wiring structure 120a. The semiconductor element 150a may be a transistor such as a metal-oxide-semiconductor field effect transistor (MOSFET). The semiconductor element 150a may include an impurity region 151a, a gate dielectric layer 152a, a gate electrode 153a and a spacer 154a. The impurity region 151a may be, for example, a well doped with impurities or a structure doped with impurities. The impurity region 151a may be, for example, a source region or a drain region of a transistor. The gate dielectric layer 152a may be provided on an active region (e.g., between a source region and a drain region) of the first semiconductor layer 110a. The gate electrode 153a may be disposed on the gate dielectric layer 152a. The spacer 154a may be provided on both sides of the gate electrode 153a to electrically insulate the gate electrode 153a from the impurity region 151a. In one or more example embodiments, the first semiconductor layer 110a may further include a device isolation structure (e.g., a shallow trench isolation structure) to separate the semiconductor element 150a from other semiconductor devices.

The wiring structure120a may be provided on the first semiconductor layer 110a. The wiring structure120a may include a wiring layer 121a, a wiring pad 123a, and a wiring insulating layer 122a surrounding the wiring layer 121a and the wiring pad 123a. The wiring layer 121a may include a multi-layer structure including wiring patterns and vias. The wiring patterns, vias, and wiring pads 123a included in the wiring layer 121a may include a metal material. For example, the wiring patterns, vias, and wiring pads 123a may include copper (Cu), aluminum (Al), silver (Ag), tin (Sn), gold (Au), nickel (Ni), lead (Pb), titanium (Ti), or at least two or more alloys thereof. The wiring pad 123a may be thick top metal (TTM). For example, the wiring pad 123a may have a thicker thickness than wiring patterns and vias included in the wiring layer 121a. The wiring insulating layer 122a may include an insulating material. For example, the wiring insulating layer 122a may include silicon oxide, silicon nitride, an insulating polymer, or a combination thereof. The wiring layer 121a may connect the semiconductor element 150a and the first through electrode 140a to the first connection pad 131a provided on a surface of the semiconductor chip 100A, using the wiring patterns, vias, and the wiring pad 123a.

The first connection pad 131a and the first insulating layer 132a surrounding a side of the first connection pad 131a may be disposed on the wiring structure 120a. The first connection pad 131a may directly contact the second connection pad 131b included in the second semiconductor chip 100B in a vertical direction (e.g., in the second direction DR2). The first insulating layer 132a may insulate the plurality of first connection pads 131a from each other by preventing the plurality of first connection pads 131a provided on the wiring structure 120a from contacting each other. The first insulating layer 132a may include an insulating material. For example, the first insulating layer 132a may include silicon oxide, silicon nitride, an insulating polymer, or a combination thereof. The first insulating layer 132a may directly contact the second insulating layer 132b included in the second semiconductor chip 100B in a vertical direction.

The first through electrode 140a may penetrate the first semiconductor layer 110a in a vertical direction (e.g., in the second direction DR2). Through electrodes 140a and 140b may be formed by drilling thousands of fine holes vertically penetrating each of the semiconductor chips 100A and 100B, and filling the holes with a conductive material to connect them with electrodes. Holes in the through electrodes 140a and 140b may be formed by deep etching. In one or more example embodiments, holes of the through electrodes 140a and 140b may be formed by a laser. The through electrodes 140a and 140b may include a conductive plug and a barrier film surrounding the conductive plug. In one or more example embodiments, the holes of the through electrodes 140a and 140b may be filled with a conductive material by electrolytic plating. In one or more example embodiments, the conductive plugs of the through electrodes 140a and 140b may include at least one of tungsten (W), aluminum (AI), copper (Cu), and an alloy thereof. The barrier film may include at least one of metal compounds such as titanium nitride (TiN), tantalum nitride (TaN), or tungsten nitride (WN). Referring to FIG. 2A, the first through electrode 140a may electrically connect the first connection pad 131a provided on the surface of the first semiconductor layer 110a to the connection pad provided on the surface of the first semiconductor layer 110a.

Referring to FIG. 2A, the junction of the second semiconductor chip 100B may include a second semiconductor layer 110b, the second connection pad 131b, the second insulating layer 132b, and the second through electrode 140b.

The second semiconductor layer 110b may include, for example, a semiconductor element such as silicon (Si) or germanium (Ge), or silicon carbide (SiC), gallium arsenide (GaAs), indium arsenide (InAs), or a compound semiconductor such as indium phosphide (InP). An active region, for example, a well doped with impurity, or a structure doped with impurity may be included on the upper surface of the second semiconductor layer 110b.

Various device isolation structures, such as a shallow trench isolation (STI) structure may be included on the upper surface of the second semiconductor layer 110b. In FIG. 2A, the second semiconductor layer 110b may be a portion adjacent to the surface of the second semiconductor chip 100B.

The second insulating layer 132b may be disposed on the second semiconductor layer 110b. The second insulating layer 132b may include an insulating material. For example, the second insulating layer 132b may include silicon oxide, silicon nitride, an insulating polymer, or a combination thereof. The second insulating layer 132b may surround a side of the second connection pad 131b and a portion of a sidewall of the second through electrode 140b. The second insulating layer 132b may directly contact the first insulating layer 132a of the first semiconductor chip 100A in a vertical direction (e.g., in the second direction DR2).

The second through electrode 140b may penetrate the second semiconductor layer 110b in a vertical direction (e.g., in the second direction DR2). Referring to FIG. 2A, the second through electrode 140b may electrically connect the second connection pad 131b provided on the surface of the second semiconductor layer 110b to the connection pad provided on the surface of the first semiconductor layer 110b.

In one or more example embodiments, the first connection pad 131a and the second connection pad 131b may include the same metal material. For example, the first connection pad 131a and the second connection pad 131b may include copper (Cu). Referring to FIG. 2A, the first connection pad 131a and the second connection pad 131b may be directly bonded by a metal-metal bonding. That is, the same metal materials may be bonded at the interface between the first connection pad 131a and the second connection pad 131b, and thus, the interface between the first connection pad 131a and the second connection pad 131b may not be visible. As a result, the first connection pad 131a and the second connection pad 131b may be integrally formed.

The first insulating layer 132a and the second insulating layer 132b may include any one of silicon oxide, silicon nitride, and tetraethyl orthosilicate (TEOS) forming oxide. The first insulating layer 132a and the second insulating layer 132b may be directly bonded by a non-metal-non-metal bonding. That is, a covalent bonding may be formed between the insulating materials at the interface between the first insulating layer 132a and the second insulating layer 132b, and thus, the interface between the first insulating layer 132a and the second insulating layer 132b may not be visible. That is, the first insulating layer 132a and the second insulating layer 132b may be integrally formed. In one or more example embodiments, the non-metal-non-metal bonding between the first insulating layer 132a and the second insulating layer 132b may be a bonding between different insulating materials. For example, the first insulating layer 132a may include tetraethyl orthosilicate (TEOS) forming oxide, and the second insulating layer may include silicon oxide.

In the bonding process, after the surface of the first semiconductor chip 100A and the surface of the second semiconductor chip 100B contact each other, the junction may be heated to a predetermined temperature (150° C. to 200° C.). As the junction is heated, the first connection pad 131a and the second connection pad 131b may expand, and accordingly, compressive stress applied to the connection pads 131a and 131b may increase. When the compressive stress applied to the first connection pad 131a and the second connection pad 131b increases excessively, the connection pads 131a and 131b may be delaminated from each other, or cracks may occur in the junction region. In one or more example embodiments, the first connection pad 131a may have a larger volume than the second connection pad 131b. Accordingly, when a difference between a width w1 of the first connection pad 131a in the first direction DR1 and a width w2 of the second connection pad 131b is excessively large, the stress applied to the connection pads 131a and 131b may increase significantly.

Referring to FIGS. 2A and 2B, the width w1 of the first connection pad 131a in the first direction DR1 and the width w2 of the second connection pad 131b in the first direction DR1 may be determined in advance to minimize stress applied to the connection pads 131a and 131b in the bonding process. Specifically, the width w1 of the first connection pad 131a in the first direction DR1 and the width w2 of the second connection pad 131b in the first direction DR1 may be determined in advance so that the width ratio w1/w2 has a predetermined range.

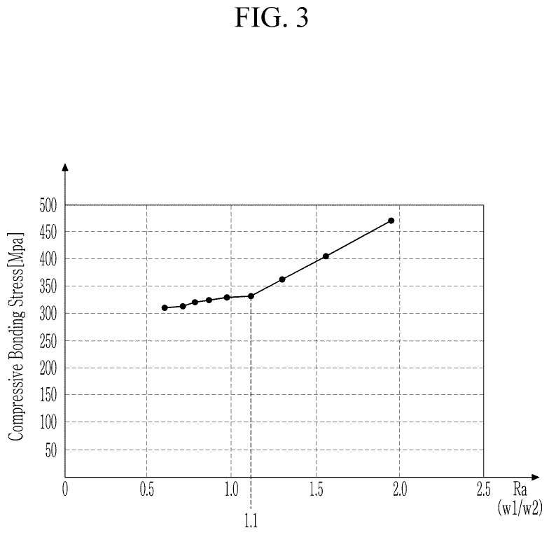

FIG. 3 is a diagram illustrating the magnitude of the stress on the connection pads according to a width ratio. A width ratio Ra may be a ratio of the width w1 of the first connection pad 131a in the first direction DR1 to the width w2 of the second connection pad 131b in the first direction DR1.

Referring to FIGS. 2B and 3, as the width ratio Ra increases, the compressive bonding stress applied to the connection pads 131a and 131b in the bonding process may increase. In this case, the compressive stress may increase with a gentle slope until the width ratio Ra becomes 1.1, and then rapidly increase when the width ratio Ra exceeds 1.1. Accordingly, in one or more example embodiments, the width w1 of the first connection pad 131a in the first direction DR1 and the width w2 of the second connection pad 131b in the first direction DR1 may be designed to have the width ratio Ra less than or equal to 1.1.

However, when the width ratio Ra is excessively small, the contact area between the first connection pad 131a and the second connection pad 131b may become small, thereby reducing the adhesion between the first connection pad 131a and the second connection pad 131b. Accordingly, the width ratio Ra may be designed to have a value greater than or equal to at least 0.5.

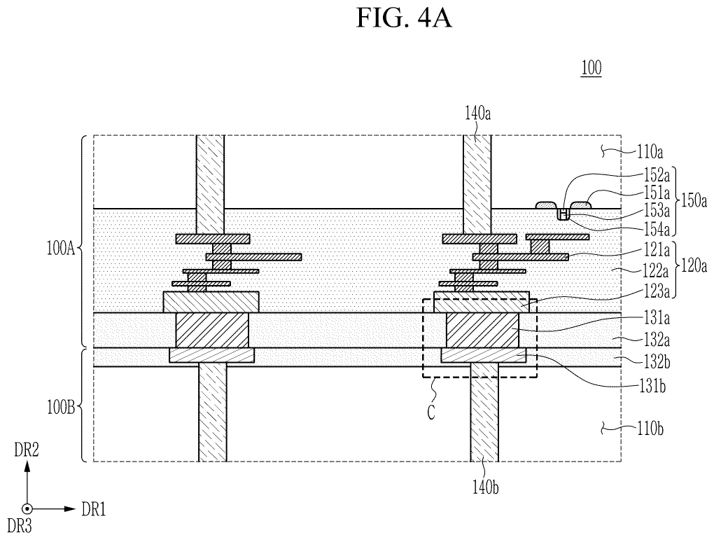

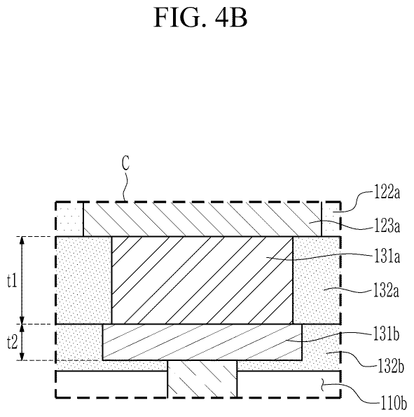

FIGS. 4A and 4B are diagrams for specifically describing a configuration of a junction of a semiconductor package according to one or more example embodiments.

Specifically, FIG. 4A is an enlarged cross-sectional view of a junction of a semiconductor package according to one or more example embodiments, and FIG. 4B is an enlarged cross-sectional view of region ‘C’ of FIG. 4A.

For example, FIG. 4A may be an enlarged view of portion ‘A’ in the semiconductor package 100 of FIG. 1, according to one or more example embodiments.

The first semiconductor chip 100A may be connected to the second semiconductor chip 100B in a flip chip method. For example, in FIG. 2A, the junction may be where a surface of the first semiconductor chip 100A and a surface of the second semiconductor chip 100B are joined together.

Referring to FIG. 4A, the junction of the first semiconductor chip 100A may include the first semiconductor layer 110a, the wiring structure 120a, the first connection pad 131a, the first insulating layer 132a, the first through electrode 140a and the semiconductor element 150a. The wiring structure120a may include a wiring layer 121a, a wiring pad 123a, and a wiring insulating layer 122a surrounding the wiring layer 121a and the wiring pad 123a. The semiconductor element 150a may include an impurity region 151a, a gate dielectric layer 152a, a gate electrode 153a and a spacer 154a. Because the specific positional relationships and functions of the components included in the first semiconductor chip 100A are the same as those of the first semiconductor chip 100A described with reference to FIG. 2A, duplicate detailed descriptions thereof are omitted herein.

Referring to FIG. 4A, the junction of the second semiconductor chip 100B may include the second semiconductor layer 110b, the second connection pad 131b, the second insulating layer 132b, and the second through electrode 140b. Because the specific positional relationships and functions of the components included in the second semiconductor chip 100B are the same as those of the first semiconductor chip 100A described with reference to FIG. 2A, duplicate detailed descriptions thereof are omitted herein.

In one or more example embodiments, the width ratio Ra of the widths of the first connection pad 131a and the second connection pad 131b in the first direction DR1 is may be determined to have the value less than or equal to 1.1, as described with reference to FIG. 2A. In one or more example embodiments, the width of the first connection pad 131a in the first direction DR1 may be smaller than the width of the second connection pad 131b in the first direction DR1.

In the bonding process, after the surface of the first semiconductor chip 100A and the surface of the second semiconductor chip 100B contact each other, the junction may be heated to a predetermined temperature (150° C. to 200° C.). As the junction is heated, the first connection pad 131a and the second connection pad 131b may expand, and accordingly, compressive stress applied to the connection pads 131a and 131b may increase. When the compressive stress applied to the first connection pad 131a and the second connection pad 131b increases excessively, the connection pads 131a and 131b may be delaminated from each other, or cracks may occur in the junction region. In one or more example embodiments, depending on the thickness of the connection pads 131a and 131b, the degree of expansion of each connection pad may be different when the junction is heated in the bonding process. In other words, depending on the thickness of the connection pads 131a and 131b, the compressive stress applied to the first connection pad 131a and the second connection pad 131b when the junction is heated in the bonding process may also change.

Referring to FIGS. 4A and 4B, a thickness t1 of the first connection pad 131a in the second direction DR2 and a thickness t2 of the second connection pad 131b in the second direction DR2 may be determined in advance to minimize stress applied to the connection pads 131a and 131b in the bonding process. Specifically, the thickness t1 of the first connection pad 131a in the second direction DR2 and the thickness t2 of the second connection pad 131b in the second direction DR2 may be determined in advance so that the thickness ratio t1/t2 has a predetermined range.

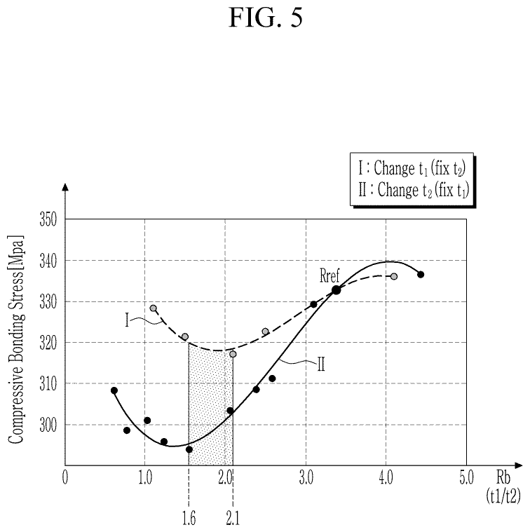

FIG. 5 is a diagram showing the size of stress applied to the connection pads according to a thickness ratio. A thickness ratio Rb may be the ratio of the thickness t1 of the first connection pad 131a in the second direction DR2 to the width t2 of the second connection pad 131b in the second direction DR2.

In FIG. 5, the graph “I” may represent the compressive stress applied to the connection pads 131a, 131b when the thickness t1 of the first connection pad 131a is changed while the thickness t2 of the second connection pad 131b is fixed, based on a reference ratio Rref. The graph “II” may represent the compressive stress applied to the connection pads 131a, 131b when the thickness t2 of the second connection pad 131b is changed while the thickness t1 of the first connection pad 131a is fixed, based on the reference ratio Rref.

Referring to graph ‘I’ of FIG. 5, if the thickness t1 of the first connection pad is changed while the thickness t2 of the second connection pad is fixed, the compressive stress applied to the connection pads 131a and 131b may have a minimum value when the thickness ratio Rb is 2.1. Referring to graph ‘II’ of FIG. 5, if the thickness t2 of the second connection pad is changed while the thickness t1 of the first connection pad is fixed, the compressive stress applied to the connection pads 131a and 131b may have a minimum value when the thickness ratio Rb is 1.6. Accordingly, in one or more example embodiments, the thickness t1 of the first connection pad 131a in the second direction DR2 and the thickness t2 of the second connection pad 131b in the second direction DR2 may be designed to have the ratio Rb greater than or equal to 1.6 and less than or equal to 2.1.

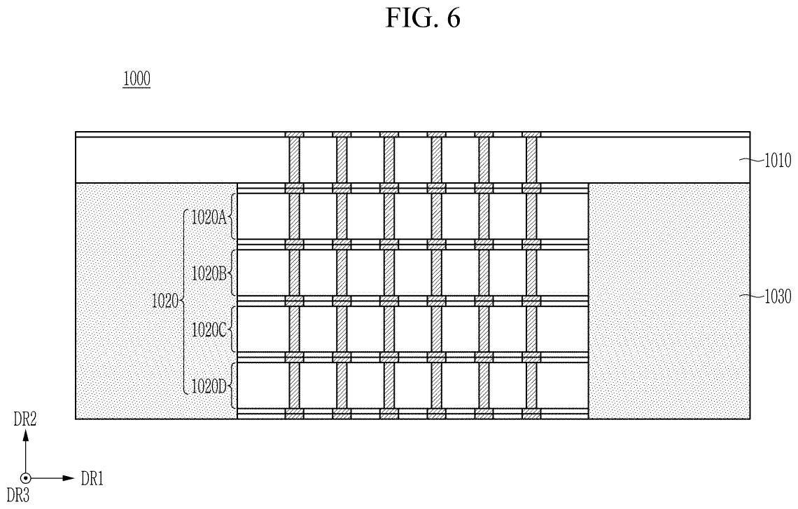

FIG. 6 is a diagram illustrating a semiconductor package according to one or more example embodiments.

Referring to FIG. 6, a semiconductor package 1000 may include a semiconductor chip stacking structure 1020, an upper die 1010, and a molding material 1030.

The semiconductor chip stacking structure 1020 may have a structure in which a plurality of semiconductor chips 1020A, 1020B, 1020C and 1020D are stacked in one direction (e.g., in the second direction DR2). The upper die 1010 may be disposed on the semiconductor chip stacking structure 1020. In one or more example embodiments, the upper die 1010 may have a larger width in the first direction DR1 compared to the semiconductor chip stacking structure 1020.

Each of the plurality of semiconductor chips 1020A, 1020B, 1020C and 1020D stacked on the semiconductor chip stacking structure 1020 may be a memory chip. The upper die 1010 may be a buffer die or a logic die. For example, the upper die 1010 may be a central processing unit (CPU) chip, a graphic processing unit (GPU) chip, or an application processor (AP) chip.

The semiconductor chip stacking structure 1020 and the upper die 1010 may be bonded by hybrid bonding. Each of the semiconductor chips 1020A, 1020B, 1020C and 1020D included in the semiconductor chip stacking structure 1020 may be bonded to each other by hybrid bonding. Hybrid bonding may be performed by a junction included in each of the semiconductor chips 1020A, 1020B, 1020C and 1020D or the upper die 1010. The junction may be a portion where the semiconductor chips contact each other when the plurality of semiconductor chips 100A, 100B, 100C and 100D are stacked and connected to each other. Alternatively, the junction may be a portion where the semiconductor chip and the upper die 1010 contact each other when any one of the plurality of semiconductor chips 1020A, 1020B, 1020C and 1020D and the upper die 1010 are connected to each other. For hybrid bonding, the same description of hybrid bonding described with reference to FIGS. 1, 2A, 2B, 3, 4A, 4B and 5 may be applied.

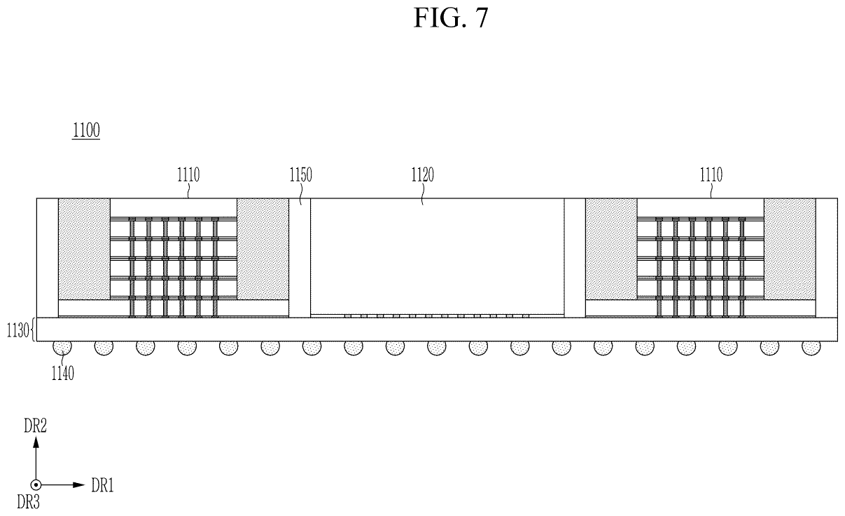

FIG. 7 is a cross-sectional view illustrating a 2.5D semiconductor package including a junction structure according to one or more example embodiments.

The semiconductor package 1100 of FIG. 7 may include a plurality of first semiconductor chips 1110, a second semiconductor chip 1120, an interposer 1130 and a molding material 1150. The first semiconductor chip 1110 may include the semiconductor stacking structure, the lower die, and the molding material described with reference to one or more example embodiments of FIG. 1. The second semiconductor chip 1120 may be a logic die.

A substrate may be disposed under the interposer 1130. Connection members may be disposed on the lower surface of the interposer 1130. In one or more example embodiments, the interposer 1130 may include a silicon interposer.

The first semiconductor chips 1110 and the second semiconductor chip 1120 may be disposed on the interposer 1130. The first semiconductor chips 1110 and the second semiconductor chip 1120 may be bonded to the interposer 1130 by hybrid bonding. The second semiconductor chip 1120 may include connection pads and an insulating layer for hybrid bonding. For hybrid bonding, the same description of hybrid bonding described with reference to one or more example embodiments of FIGS. 1, 2A, 2B, 3, 4A, 4B and 5 may be applied.

The second semiconductor chip 1120 may be disposed side-by-side with the first semiconductor chips 1110 between the first semiconductor chips 1110. In one or more example embodiments, the second semiconductor chip 1120 may include a system on chip (SoC). In one or more example embodiments, the second semiconductor chip 1120 may include a central processing unit (CPU) or a graphic processing unit (GPU).

The molding material 1150 may be disposed on the interposer 1130, and may mold the first semiconductor chips 1110 and the second semiconductor chip 1120. The molding material 1150 may serve to protect and insulate the first semiconductor chips 1110 and the second semiconductor chip 1120. In one or more example embodiments, the molding material 1150 may comprise a thermosetting resin such as epoxy resin. In one or more example embodiments, the molding material 1150 may be an epoxy molding compound (EMC). In one or more example embodiments, the process of molding with the molding material 1150 may include a compression molding or transfer molding process.

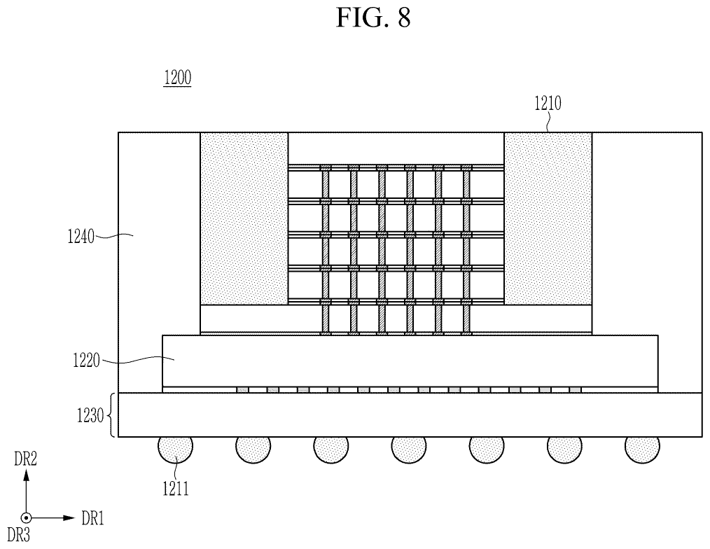

FIG. 8 is a cross-sectional view illustrating a 3D semiconductor package including a junction structure according to one or more example embodiments.

A semiconductor package 1200 of FIG. 8 may include a first semiconductor chip 1210, a second semiconductor chip 1220, an interposer 1230 and a molding material 1240. The first semiconductor chip 1210 may include the semiconductor stacking structure, the lower die and the molding material described with reference to one or more example embodiments of FIG. 1. The second semiconductor chip 1220 may be a logic die.

A substrate may be disposed below the interposer 1230. Connection members may be disposed on the lower surface of the interposer 1230. In one or more example embodiments, the interposer 1230 may include a silicon interposer. The second semiconductor chip 1220 may be disposed on the interposer 1230. The second semiconductor chip 1220 may be bonded to the interposer 1230 by hybrid bonding. For hybrid bonding, the same description of hybrid bonding described with reference to one or more example embodiments of FIGS. 1, 2A, 2B, 3, 4A, 4B, 5, 6, 7, 8 and 9 may be applied.

In one or more example embodiments, the second semiconductor chip 1220 may include a system on chip (SoC). In one or more example embodiments, the second semiconductor chip 1220 may include a central processing unit (CPU) or a graphic processing unit (GPU).

The first semiconductor chip 1210 may be disposed on the second semiconductor chip 1220. The first semiconductor chip 1210 may be bonded to the second semiconductor chip 1220 by hybrid bonding. For hybrid bonding, the same description of hybrid bonding described with reference to one or more example embodiments of FIGS. 1, 2A, 2B, 3, 4A, 4B and 5 may be applied.

The molding material 1240 may be disposed on the interposer 1230, and may mold the first semiconductor chip 1210 and the second semiconductor chip 1220. The molding material 1240 may serve to protect and insulate the first semiconductor chip 1210 and the second semiconductor chip 1220. In one or more example embodiments, the molding material 1240 may comprise a thermosetting resin such as epoxy resin. In one or more example embodiments, the molding material 1240 may be an epoxy molding compound (EMC). In one or more example embodiments, the process of molding with the molding material 1240 may include a compression molding or transfer molding process.

According to one or more embodiments, when semiconductor chips are bonded to each other in a bonding process, a width ratio or a thickness ratio capable of minimizing stress applied to bonding pads may be provided, thereby improving the reliability of a junction.

While example embodiments have been particularly shown and described above, it will be apparent to those skilled in the art that various changes in form and details may be made therein without departing from the spirit and scope of the appended claims.

What is claimed is:

1. A semiconductor package comprising:
a first semiconductor chip comprising:
a first semiconductor layer comprising a surface which extends in a first direction; and
a first connection pad provided on the surface of the first semiconductor layer; and
a second semiconductor chip comprising:
a second semiconductor layer; and
a second connection pad provided on a surface of the second semiconductor layer,
wherein the first connection pad is directly connected to the second connection pad,
wherein the first connection pad is provided on the second connection pad in a second direction perpendicular to the first direction, and
wherein a ratio of a width of the second connection pad in the first direction to a width of the first connection pad in the first direction is less than or equal to 1.1 and greater than or equal to 0.5.

2. The semiconductor package of claim 1, wherein the first semiconductor chip comprises a first insulating layer provided on the surface of the first semiconductor layer and surrounding a side surface of the first connection pad,
wherein the second semiconductor chip comprises a second insulating layer provided on the surface of the second semiconductor layer and surrounding a side surface of the second connection pad, and
wherein the first insulating layer comprises a first insulating material and the second insulating layer comprises a second insulating material that is different than the first insulating material.

3. The semiconductor package of claim 2, wherein the first insulating layer comprises silicon oxide, and
wherein the second insulating layer comprises tetraethyl orthosilicate (TEOS).

4. The semiconductor package of claim 2, wherein the first insulating layer is directly connected to the second insulating layer, and
wherein the first insulating layer is provided on the second insulating layer in the second direction.

5. The semiconductor package of claim 2, wherein the first semiconductor chip comprises a wiring structure provided between the surface of the first semiconductor layer and the first insulating layer,
wherein the wiring structure is provided between the surface of the first semiconductor layer and the first connection pad,
wherein the wiring structure comprises a wiring pad electrically connected to the first connection pad, and
wherein the first insulating layer comprises a surface in direct contact with the surface of the first semiconductor layer.

6. The semiconductor package of claim 1, wherein the first connection pad and the second connection pad comprise a same metal material.

7. The semiconductor package of claim 1, wherein a thickness of the first connection pad in the second direction is greater than a thickness of the second connection pad in the second direction.

8. The semiconductor package of claim 1, wherein a ratio of a thickness of the first connection pad in the second direction to a thickness of the second connection pad in the second direction is greater than or equal to 1.6 and less than or equal to 2.1.

9. A semiconductor package comprising:
a first semiconductor chip comprising:
a first semiconductor layer comprising a surface which extends in a first direction; and
a first connection pad provided on the surface of the first semiconductor layer; and
a second semiconductor chip comprising:
a second semiconductor layer; and
a second connection pad provided on a surface of the second semiconductor layer,
wherein the first connection pad is directly connected to the second connection pad,
wherein the first connection pad is provided on the second connection pad in a second direction perpendicular to the first direction, and
wherein a ratio of a thickness of the first connection pad in the second direction to a thickness of the second connection pad in the second direction is greater than or equal to 1.6 and less than or equal to 2.1.

10. The semiconductor package of claim 9, wherein the first semiconductor chip comprises a first insulating layer provided on the surface of the first semiconductor layer and surrounding a side surface of the first connection pad,
wherein the second semiconductor chip comprises a second insulating layer provided on the surface of the second semiconductor layer and surrounding a side surface of the second connection pad, and
wherein the first insulating layer comprises a first insulating material and the second insulating layer comprises a second insulating material that is different than the first insulating material.

11. The semiconductor package of claim 10, wherein the first insulating layer comprises silicon oxide, and
wherein the second insulating layer comprises tetraethyl orthosilicate (TEOS).

12. The semiconductor package of claim 10, wherein the first insulating layer is directly connected to the second insulating layer, and
wherein the first insulating layer is provided on the second insulating layer in the second direction.

13. The semiconductor package of claim 10, wherein the first semiconductor chip comprises a wiring structure provided between the surface of the first semiconductor layer and the first insulating layer,
wherein the wiring structure is provided between the surface of the first semiconductor layer and the first connection pad,
wherein the wiring structure comprises a wiring pad electrically connected to the first connection pad, and
wherein the first insulating layer comprises a surface in direct contact with the surface of the first semiconductor layer.

14. The semiconductor package of claim 9, wherein the first connection pad and the second connection pad comprise a same metal material.

15. The semiconductor package of claim 9, wherein a width of the first connection pad in the first direction is greater than a width of the second connection pad in the first direction.

16. A semiconductor package comprising:
an interposer,
a logic die provided on the interposer; and
a high bandwidth memory provided on the interposer,
wherein the high bandwidth memory comprises:
a buffer die;
a first semiconductor chip provided on the buffer die and comprising:
a first semiconductor layer comprising a surface which extends in a first direction; and
a first connection pad provided on the surface of the first semiconductor layer; and
a second semiconductor chip comprising:
a second semiconductor layer; and
a second connection pad provided on a surface of the second semiconductor layer,
wherein the first connection pad is directly connected to the second connection pad,
wherein the first connection pad is provided on the second connection pad in a second direction perpendicular to the first direction,
wherein a ratio of a width of the second connection pad in the first direction to a width of the first connection pad in the first direction is less than or equal to 1.1 and greater than or equal to 0.5, and
wherein the semiconductor package further comprises a molding material provided on the buffer die and molding the first semiconductor chip and the second semiconductor chip.

17. The semiconductor package of claim 16, wherein a ratio of a thickness of the first connection pad in the second direction to a thickness of the second connection pad in the second direction is greater than or equal to 1.6 and less than or equal to 2.1.

18. The semiconductor package of claim 16, wherein the first semiconductor chip comprises a wiring structure provided between the surface of the first semiconductor layer and a first insulating layer,
wherein the wiring structure is provided between the surface of the first semiconductor layer and the first connection pad,
wherein the wiring structure comprises a wiring pad electrically connected to the first connection pad,
wherein the first insulating layer comprises a surface in direct contact with the surface of the first semiconductor layer.

19. The semiconductor package of claim 16, wherein the first semiconductor chip comprises a first insulating layer provided on one surface of the first semiconductor layer and surrounding a side surface of the first connection pad,
wherein the second semiconductor chip comprises a second insulating layer provided on the surface of the second semiconductor layer and surrounding a side surface of the second connection pad, and
wherein the first insulating layer comprises a first insulating material and the second insulating layer comprises a second insulating material that is different than the first insulating material.

20. The semiconductor package of claim 19, wherein the first insulating layer comprises silicon oxide, and
wherein the second insulating layer comprises tetraethyl orthosilicate (TEOS).
